(19) United States
(12) Patent Application Publication
(10) Pub. No.: US 2013/0002332 A1
(43) Pub. Date: Jan. 3, 2013

(54) BUS SWITCH CIRCUIT

(75) Inventor: Akira TAKIBA, Yokohama-shi (JP)

(73) Assignee: KABUSHIKI KAISHA TOSHIBA, Tokyo (JP)

(21) Appl. No.: 13/419,460

(22) Filed: Mar. 14, 2012

(30) Foreign Application Priority Data
Jun. 28, 2011 (JP) 2011-143041

(51) Int. Cl. H03H 11/26

(52) U.S. Cl. 327/288; 327/261

(57) ABSTRACT

A bus switch circuit according to an embodiment includes a signal transmission circuit connected between a first terminal and a second terminal. The bus switch circuit includes a first switch element controlled by a first control signal. The bus switch circuit includes a second switch element controlled by a second control signal. The bus switch circuit includes a delay signal generating circuit that outputs a delay signal based on a first signal varying with a first voltage applied to the first terminal and a second signal varying with a second voltage applied to the second terminal. The bus switch circuit includes a control signal generating circuit that outputs the first control signal and the second control signal based on the first signal, the second signal, and the delay signal.

### CROSS-REFERENCE TO RELATED APPLICATION

This application is based upon and claims the benefit of priority from the prior Japanese Patent Application No. 2011-143041, filed on Jun. 28, 2011, the entire contents of which are incorporated herein by reference.

### FIELD

Embodiments described herein relate generally to a bus switch circuit.

### BACKGROUND

In system large scale integrations (LSIs) typified by a central processing unit (CPU) and a baseband integrated circuit (IC), power supply voltages have been reduced in response to used processes and lower power consumption.

In a conventionally used system and an analog signal processing system, however, power supply voltages have not been rapidly reduced because compatibility with conventional systems needs to be maintained.

Thus, signal transmission between circuits with different power supply voltages requires a bus switch circuit that converts a signal level.

### BRIEF DESCRIPTION OF THE DRAWINGS

FIG. 1 is a circuit diagram illustrating a circuit configuration of a bus switch circuit 100X according to a comparative example;

FIG. 2 is a diagram showing a relationship between a time and voltages VA and VB applied to first and second terminals of the bus switch circuit 100X according to the comparative example illustrated in FIG. 1;

FIG. 3 is a waveform chart illustrating signal waveforms of first and second terminals TA and TB and nodes α and β of the bus switch circuit 100X of the comparative example in FIG. 1, in the case where a load capacitance connected to the first terminal TA is larger than a load capacitance connected to the second terminal TB;

FIG. 4 is a circuit diagram illustrating an example of a circuit configuration of a bus switch circuit 100 according to a first embodiment;

FIG. 5 is a waveform chart showing an example of signal waveforms of the bus switch circuit 100 illustrated in FIG. 4;

FIG. 6 is a waveform chart showing the signal waveforms of the bus switch circuit 100 according to the first embodiment illustrated in FIG. 4, in the case where a load capacitance connected to the first terminal TA is larger than a load capacitance connected to the second terminal TB;

FIG. 7 is a circuit diagram illustrating an example of a circuit configuration of a pulse generating circuit 102 according to a second embodiment;

FIG. 8 is a circuit diagram illustrating an example of a circuit configuration of a pulse generating circuit 102 according to a third embodiment;

FIG. 9 is a circuit diagram illustrating an example of a circuit configuration of a pulse generating circuit 102 according to a fourth embodiment;

FIG. 10 is a waveform chart showing an example of signal waveforms of the bus switch circuit 100 including the pulse generating circuit 102 illustrated in FIG. 9; and

FIG. 11 is a circuit diagram illustrating an example of a circuit configuration of a pulse generating circuit 102 according to a fifth embodiment.

### DETAILED DESCRIPTION

A bus switch circuit according to an embodiment includes a signal transmission circuit connected between a first terminal and a second terminal to transmit a signal between the first terminal and the second terminal. The bus switch circuit includes a first switch element connected between the first terminal and a first voltage line fed with a first power supply voltage, and controlled by a first control signal. The bus switch circuit includes a second switch element connected between the second terminal and a second voltage line fed with a second power supply voltage, and controlled by a second control signal. The bus switch circuit includes a delay signal generating circuit that outputs a delay signal based on a first signal varying with a first voltage applied to the first terminal and a second signal varying with a second voltage applied to the second terminal. The bus switch circuit includes a control signal generating circuit that outputs the first control signal and the second control signal based on the first signal, the second signal, and the delay signal.

Hereafter, a bus switch circuit according to the present invention will be described more specifically with reference to the drawings.

### Comparative Example

A comparative example of embodiments will be described below.

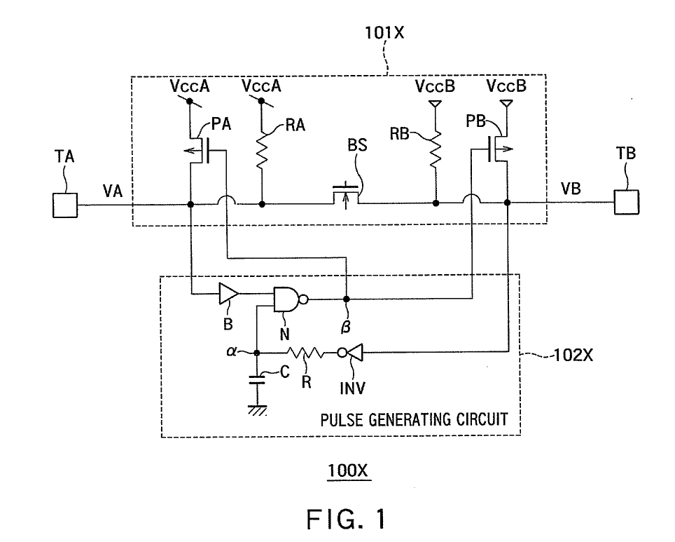

FIG. 1 is a circuit diagram illustrating the circuit configuration of a bus switch circuit 100X according to the comparative example.

As illustrated in FIG. 1, the bus switch circuit 100X includes a first terminal TA, a second terminal TB, a signal level converting circuit 101X, and a pulse generating circuit 102X.

The signal level converting circuit 101X includes a first resistance element RA, a second resistance element RB, a bus switch element BS, a first assisting switch element (first switch element) PA, and a second assisting switch element (second switch element) PB.

The pulse generating circuit 102X includes an inverter INV, a resistance element R and a capacitor C that constitute a delay circuit, a NAND circuit N, and a buffer B.

A second power supply voltage VccB is set higher than a first power supply voltage VccA. The gate of the bus switch element BS is fed with the second power supply voltage VccB.

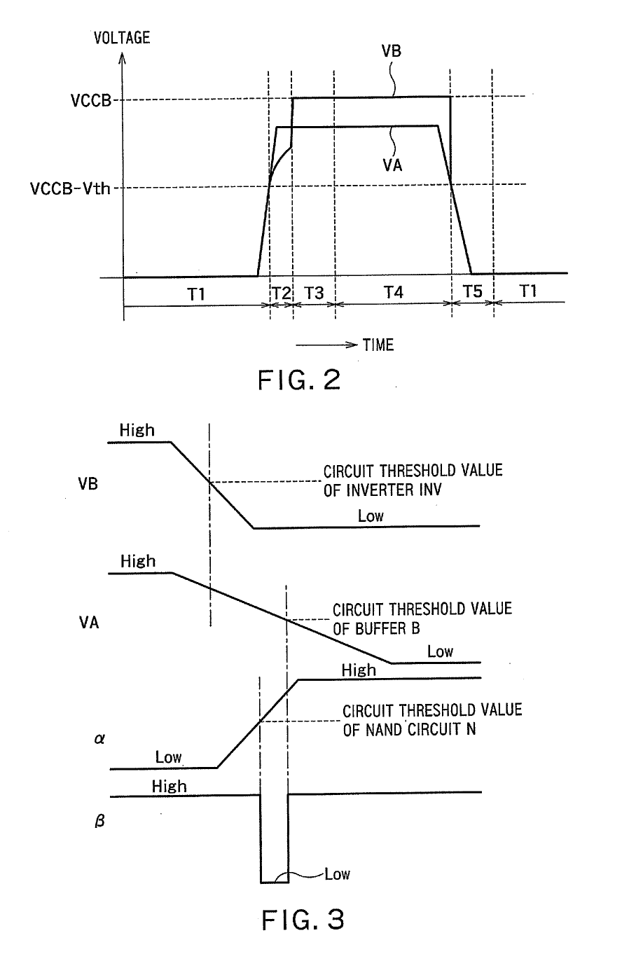

FIG. 2 shows the relationship between a time and voltages VA and VB applied to the first and second terminals of the bus switch circuit 100X according to the comparative example illustrated in FIG. 1.

As shown in FIG. 2, in the bus switch circuit 100X of the comparative example (periods T1 to T2), the first terminal TA changes from, for example, “Low” level (ground voltage) to “High” level (first power supply voltage VccA). In the period T1, the bus switch element BS is turned on by the second power supply voltage VccB applied to the gate of the bus switch element BS. In the period T2, the voltage of the first terminal TA is not lower than the second power supply voltage VccB-threshold voltage Vth, so that the bus switch element BS is turned off.

When the bus switch element BS is turned off, the voltage VA is at “High” level, so that the output of the buffer B is at “High” level. This allows the voltage of a node β connected to the output of the NAND circuit N to change from “High” level to “Low” level. After the lapse of the delay time of the delay circuit, the voltage of a node a changes to “Low” level, so that the voltage of the node β changes from “Low” level to “High” level.

In other words, in the bus switch circuit 100X of the comparative example, the pulse generating circuit 102X generates a one-shot pulse signal having a certain width when the first terminal TA changes from “Low” level to “High” level.

This pulse signal turns on the first and second assisting switch elements PA and PB connected to the first and second terminals TA and TB.

Thus, the voltage VB of the second terminal TB is raised to the second power supply voltage VccB and an output signal at a predetermined level is outputted from the second terminal TB (period T3 in FIG. 2). In other words, faster signal transmission is achieved.

After that, the first terminal TA changes from “High” level to “Low” level (periods T4 to T5 in FIG. 2). At this point, since the bus switch element BS is turned on, the voltage (output voltage) VB of the second terminal TB decreases with a reduction in the first voltage (input voltage) VA of the first terminal TA; meanwhile, the voltage of the node β does not change and thus the pulse signal is not generated. In other words, the first and second assisting switch elements PA and PB are kept turned off.

The following will discuss a problem in signal transmission from the second terminal TB to the first terminal TA in the bus switch circuit 100X of the comparative example illustrated in FIG. 1. In this case, particularly, a load capacitance connected to the first terminal TA is larger than a load capacitance connected to the second terminal TB.

FIG. 3 is a waveform chart illustrating the signal waveforms of the first and second terminals TA and TB and the nodes α and β of the bus switch circuit 100X of the comparative example in FIG. 1, in the case where the load capacitance connected to the first terminal TA is larger than the load capacitance connected to the second terminal TB.

As illustrated in FIG. 3, for example, when the voltage VB of the second terminal TB changes from “High” level to “Low” level, the voltage VA of the first terminal TA also changes from “High” level to “Low” level.

In this case, the large load capacitance connected to the first terminal TA causes a change of the voltage VA to be inclined less than a change of the voltage VB. Thus, the voltage VA falls to or below the circuit threshold value of the buffer B after the voltage of the node a rises to or above the circuit threshold value of the NAND circuit N.

Since the voltage of the node a rises to or above the circuit threshold value of the NAND circuit N, the voltage of the node β changes from “High” level to “Low” level. After that, the voltage VA falls to or below the circuit threshold value of the buffer B, so that the voltage of the node 13 changes from “Low” level to “High” level.

Thus, also in this case, the pulse generating circuit 102X generates a one-shot pulse signal. This pulse signal turns on the first and second assisting switch elements PA and PB.

In other words, although a “Low” level signal is to be transmitted, the generated pulse signal may raise the first and second terminals TA and TB to “High” level so as to output a “High” level signal from the first terminal TA.

As described above, unfortunately in the bus switch circuit 100X of the comparative example, a predetermined signal cannot be transmitted from the second terminal TB to the first terminal TA in the case where the load capacitance connected to the first terminal TA increases.

The following embodiments will propose a bus switch circuit that can transmit a predetermined signal with higher reliability regardless of a load capacitance connected to an terminal.

The embodiments will be described below with reference to the accompanying drawings.

### First Embodiment

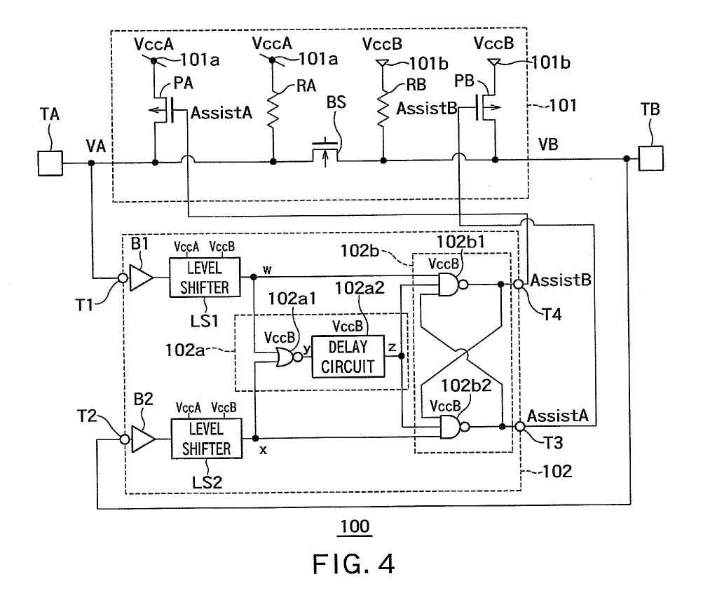

FIG. 4 is a circuit diagram illustrating an example of the circuit configuration of a bus switch circuit 100 according to a first embodiment.

As illustrated in FIG. 4, the bus switch circuit 100 includes a first terminal TA, a second terminal TB, a signal level converting circuit 101, and a pulse generating circuit 102.

The first terminal TA is connected to, for example, a first logic circuit (not shown). A signal is inputted from the first logic circuit to the first terminal TA or a signal is outputted from the first terminal TA to the first logic circuit.

The second terminal TB is connected to, for example, a second logic circuit (not shown). A signal is inputted from the second logic circuit to the second terminal TB or a signal is outputted from the second terminal TB to the second logic circuit.

In some cases, for example, a load capacitance connected to the first terminal TA is larger than a load capacitance connected to the second terminal TB. The load capacitance connected to the first terminal TA may be smaller than the load capacitance connected to the second terminal TB (that is, varying load capacitances) or the load capacitances connected to the terminals may be equal to each other.

As illustrated in FIG. 4, the signal level converting circuit 101 includes, for example, a bus switch element (signal transmission circuit) BS, a first assisting switch element PA, a second assisting switch element PB, a first resistance element RA, and a second resistance element RB.

The bus switch element BS is connected between the first terminal TA and the second terminal TB. The bus switch element BS is a signal transmission circuit, e.g., a MOS transistor for transmitting a signal between the first terminal TA and the second terminal TB. In this case, the bus switch element BS has one end (source) connected to the first terminal TA, the other end (drain) connected to the second terminal TB, and a gate fed with a second power supply voltage VccB. Thus, the bus switch element BS is turned on when the voltage of the first terminal TA is not higher than a predetermined level.

The signal transmission circuit may be a switch element other than a MOS transistor or a circuit such as a buffer for transmitting a signal between the first terminal TA and the second terminal TB.

The first assisting switch element PA is connected between the first terminal TA and a first voltage line (first power supply) 101a fed with a first power supply voltage VccA.

The first assisting switch element PA is turned on/off by a first assist control signal (first control signal) AssistA. For example, the first assisting switch element PA is turned on by the first assist control signal AssistA, so that a first voltage VA of the first terminal TA is pulled up to the first power supply voltage VccA.

The first assisting switch element PA is, for example, a MOS transistor. The first assist control signal AssistA is applied to the gate of the first assisting switch element PA. The first assisting switch element PA may be a switch element other than a MOS transistor.

The second assisting switch element PB is connected between the second terminal TB and a second voltage line (second power supply) 101b fed with the second power supply voltage VccB. The second assisting switch element PB is turned on/off by a second assist control signal (second control signal) AssistB. For example, the second assisting switch element PB is turned by the second assist control signal AssistB, so that a second voltage VB of the second terminal TB is pulled up to the second power supply voltage VccB.

The second assisting switch element PB is, for example, a MOS transistor. The second assist control signal AssistB is applied to the gate of the second assisting switch element PB. The second assisting switch element PB may be a switch element other than a MOS transistor.

The first resistance element RA is connected between the first terminal TA and the first voltage line 101a.

The second resistance element RB is connected between the second terminal TB and the second voltage line 101b.

As illustrated in FIG. 4, the pulse generating circuit 102 includes a first buffer B1, a second buffer B2, a first level shifter LS1, a second level shifter LS2, a delay signal generating circuit 102a, and an assist control signal generating circuit (control signal generating circuit) 102b.

The first buffer B1 has an input connected to the first terminal TA via a terminal T1 and an output connected to the first level shifter LS1. The first buffer B1 is fed with the first voltage VA of the first terminal TA, shapes the first voltage VA, and then outputs the voltage to the first level shifter LS1. The first buffer B1 is operated by the first power supply voltage VccA.

The second buffer B2 has an input connected to the second terminal TB via a terminal T2 and an output connected to the second level shifter LS2. The second buffer B2 is fed with the voltage of the second terminal TB, shapes the voltage, and then outputs the voltage to the second level shifter LS2. The second buffer B2 is operated by the first power supply voltage VccA.

The first and second buffers B1 and B2 may be optionally omitted.

The first level shifter LS1 outputs a first signal w obtained by converting the level of the signal outputted from the first buffer B1 (from the first power supply voltage VccA to the second power supply voltage VccB).

The second level shifter LS2 outputs a second signal x obtained by converting the level of the signal outputted from the second buffer B2 (from the first power supply voltage VccA to the second power supply voltage VccB).

In the first embodiment, the second power supply voltage VccB is set higher than the first power supply voltage VccA. As will be described later, the second power supply voltage VccB may be set equal to the first power supply voltage VccA. In this case, the first and second level shifters LS1 and LS2 may be omitted as will be described later.

The delay signal generating circuit 102a outputs a delay signal z based on the first signal w varying with the first voltage VA applied to the first terminal TA and the second signal x varying with the second voltage VB applied to the second terminal TB.

The delay signal generating circuit 102a includes, for example, a NOR circuit 102a1 and a delay circuit 102a2. The NOR circuit 102a1 is fed with the first signal w and the second signal x and outputs an operation signal y obtained by performing a NOR operation on the inputted first and second signals w and x.

The delay circuit 102a2 is fed with the operation signal y and outputs the delay signal z obtained by delaying the inputted operation signal y by a preset delay time.

The assist control signal generating circuit 102b outputs the first assist control signal AssistA and the second assist control signal AssistB based on the first signal w, the second signal x, and the delay signal z.

The assist control signal generating circuit 102b includes, for example, a first NAND circuit 102b1 and a second NAND circuit 102b2.

The first NAND circuit 102b1 is fed with the first signal w, the delay signal z, and the first assist control signal AssistA and outputs, via a terminal. T4, the second assist control signal AssistB obtained by performing a NAND operation on the inputted signals.

The second NAND circuit 102b2 is fed with the second signal x, the delay signal z, and the second assist control signal AssistB and outputs, via a terminal T3, the first assist control signal AssistA obtained by performing a NAND operation on the inputted signals.

The operations of the bus switch circuit 100 configured thus will be described below.

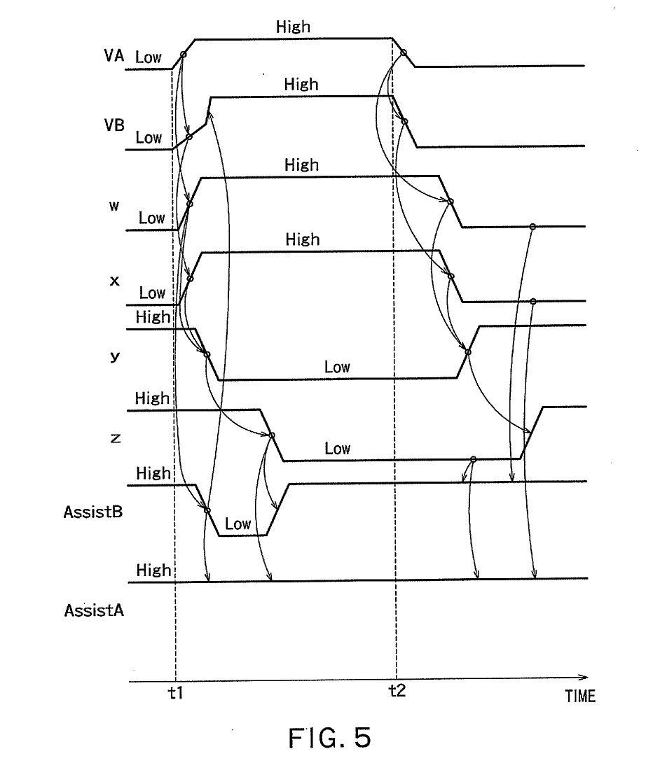

FIG. 5 is a waveform chart showing an example of the signal waveforms of the bus switch circuit 100 illustrated in FIG. 4. FIG. 5 shows signal transmission from the first terminal TA to the second terminal TB.

As shown in FIG. 5, a “High” level signal is inputted to the first terminal TA at time t1, so that the first voltage VA of the first terminal TA changes from “Low” level (e.g., a ground voltage) to “High” level (the first power supply voltage VccA). In response to the change of the first voltage VA, the second voltage VB of the second terminal TB starts changing from “Low” level to “High” level (the second power supply voltage VccB).

Then, the first signal w changes from “Low” level to “High” level in response to the change of the first voltage VA.

The first NAND circuit. 102b1 of the assist control signal generating circuit 102b changes the second assist control signal AssistB from “High” level to “Low” level in response to the change of the first signal w.

Furthermore, the second signal x changes from “Low” level to “High” level in response to the change of the second voltage VB.

As described above, the second assist control signal AssistB is at “Low” level, so that the second NAND circuit 102b2 of the assist control signal generating circuit 102b keeps the first assist control signal AssistA at “High” level regardless of the change of the second signal x.

The NOR circuit 102a1 of the delay signal generating circuit 102a changes the logic of the operation signal y from “High” level to “Low” level when the second signal x changes to “High” level in response to the change of the first signal w to “High” level.

Then, the delay circuit 102a2 of the delay signal generating circuit 102a changes the logic of the delay signal z from “High” level to “Low” level after the lapse of the delay time from the change of the logic of the operation signal y.

Specifically, the delay signal generating circuit 102a changes the logic of the delay signal z from “High” level to “Low” level after the lapse of the preset delay time from the time when the second signal x changes in response to the change of the first signal w.

Then, the first NAND circuit 102b1 changes the second assist control signal AssistB from “Low” level to “High” level in response to the change of the logic of the delay signal z.

The second NAND circuit 102b2 keeps the first assist control signal AssistA at “High” level in response to the change of the logic of the delay signal z.

As described above, in the case where the first voltage VA rises (changes to the first power supply voltage VccA), the assist control signal generating circuit 102b outputs the second assist control signal AssistB so as to turn on the second assisting switch element PB until the logic of the delay signal z changes after the change of the first signal w.

Specifically, in the case where the first voltage VA rises, the pulse generating circuit 102 generates a one-shot pulse signal for turning on the second assisting switch element PB.

Thus, the voltage VB of the second terminal TB is raised to the second power supply voltage VccB and a “High” level output signal is outputted from the second terminal TB. In other words, faster signal transmission is achieved.

At time t2, the first voltage VA of the first terminal TA changes from “High” level to “Low” level. In response to the change of the first voltage VA, the second voltage VB of the second terminal TB starts changing from “High” level to “Low” level.

Then, the first signal w changes from “High” level to “Low” level in response to the change of the first voltage VA.

The first NAND circuit 102b1 keeps the second assist control signal AssistB at “High” level regardless of the change of the first signal w because the logic of the delay signal z is at “Low” level.

In response to the change of the second voltage VB, the second signal x changes from “High” level to “Low” level.

The second NAND circuit 102b2 keeps the first assist control signal AssistA at “High” level regardless of the change of the second signal x because the logic of the delay signal z is at “Low” level.

The NOR circuit 102a1 changes the logic of the operation signal y from “Low” level to “High” level when the second signal x changes to “Low” level in response to the change of the first signal w to “Low” level.

Then, the delay circuit 102a2 changes the logic of the delay signal z from “Low” level to “High” level after the lapse of the delay time from the change of the logic of the operation signal y.

Specifically, the delay signal generating circuit 102a changes the logic of the delay signal z from “Low” level to “High” level after the lapse of the preset delay time from the time when the second signal x changes in response to the change of the first signal w.

Then, the first NAND circuit 102b1 keeps the second assist control signal AssistB at “High” level regardless of the change of the logic of the delay signal z because the first signal w is at “Low” level.

Moreover, the second NAND circuit 102b2 keeps the first assist control signal AssistA at “High” level regardless of the change of the logic of the delay signal z because the second signal x is at “Low” level.

As described above, in the case where the first voltage VA falls (changes to the ground voltage), the assist control signal generating circuit 102b outputs the second assist control signal AssistB so as to turn off the second assisting switch element PB until the logic of the delay signal z changes after the change of the first signal w.

Specifically, in the case where the first voltage VA falls, the pulse generating circuit 102 does not generate a one-shot pulse signal for turning on the second assisting switch element PB.

Thus, a “Low” level output signal is outputted from the first terminal TA.

Moreover, signal transmission from the second terminal TB to the first terminal TA can be similarly described. In this case, the order of operations is changed when the input directions of signals are switched. In this case, the delay signal generating circuit 102a changes the logic of the delay signal z after the lapse of the preset delay time from the time when the first signal w changes in response to the change of the second signal x.

Then, in the case where the second voltage VB rises (changes to the second power supply voltage VccB), the assist control signal generating circuit 102b outputs the first assist control signal AssistA so as to turn on the first assisting switch element PA until the logic of the delay signal z changes after the change of the second signal x. Thus, the first assist control signal AssistA is at “Low” level over a certain range and the second assist control signal AssistB is kept at “High” level.

Hence, in the case where the second voltage VB rises, the pulse generating circuit 102 generates a one-shot pulse signal for turning on the first assisting switch element PA. This allows the voltage VA of the first terminal TA to be raised to the first power supply voltage VccA and a “High” level output signal is outputted from the first terminal TA. In other words, faster signal transmission is achieved.

In the case where the second voltage VB falls (changes to the ground voltage), the assist control signal generating circuit 102b outputs the first assist control signal AssistA so as to turn off the first assisting switch element PA until the logic of the delay signal z changes after the change of the second signal x.

Therefore, the first assist control signal AssistA and the second assist control signal AssistB are kept at “High” level.

Specifically, in the case where the second voltage VB falls, the pulse generating circuit 102 does not generate a one-shot pulse signal for turning on the second assisting switch element PB.

Thus, the “Low” level output signal is outputted from the first terminal TA.

The following will describe signal transmission from the second terminal TB to the first terminal TA in the case where the load capacitance connected to the first terminal TA is larger than the load capacitance connected to the second terminal TB, which causes a problem in the comparative example.

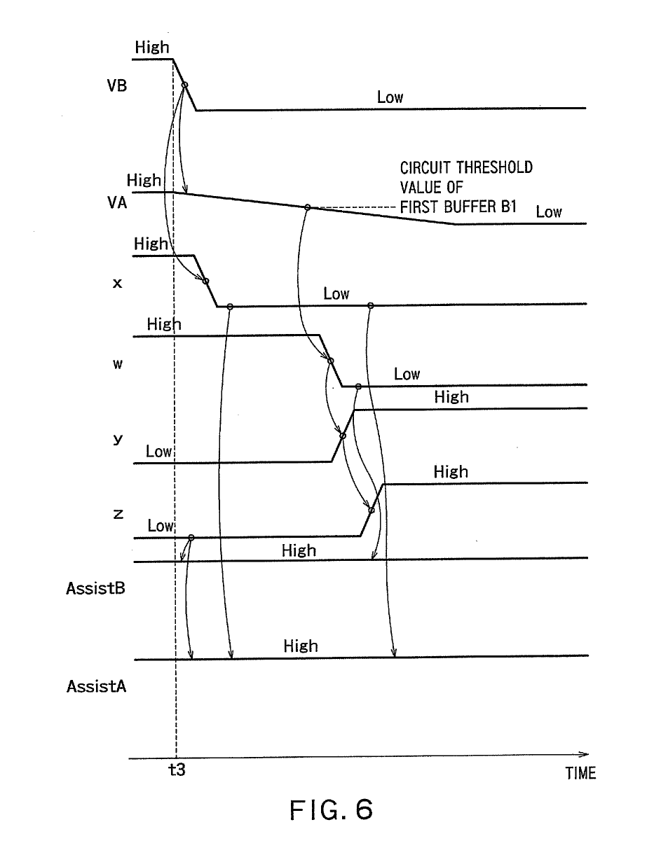

FIG. 6 is a waveform chart showing the signal waveforms of the bus switch circuit 100 according to the first embodiment illustrated in FIG. 4, in the case where the load capacitance connected to the first terminal TA is larger than the load capacitance connected to the second terminal TB.

As shown in FIG. 6, first at time t3, the second voltage VB of the second terminal. TB changes from “High” level to “Low” level. In response to the change of the second voltage VB, the first voltage VA of the first terminal TB starts changing from “High” level to “Low” level.

Then, the second signal x changes from “High” level to “Low” level in response to the change of the second voltage VB. The second NAND circuit 102b2 keeps the first assist control signal AssistA at “High” level regardless of the change of the second signal x because the logic of the delay signal z is at “Low” level.

As described above, the load capacitance connected to the first terminal TA is larger than the load capacitance connected to the second terminal TB, which causes the change of the second voltage VB to be inclined less than that of the first voltage VA. Thus, it takes a longer time period for the first voltage VA to fall below the circuit threshold value of the first buffer B1 than in the case where the load capacitance connected to the first terminal TA is smaller.

When the first voltage VA falls below the circuit threshold value of the first buffer B1, the first signal w changes from “High” level to “Low” level. The first NAND circuit 102b1 keeps the first assist control signal AssistA at “High” level regardless of the change of the first signal w because the logic of the delay signal z is at “Low” level.

The NOR circuit 102a1 changes the logic of the operation signal y from “Low” level to “High” level when the first signal w changes to “Low” level in response to the change of the second signal x to “Low” level.

Then, the delay circuit 102a2 changes the logic of the delay signal z from “Low” level to “High” level after the lapse of the delay time from the change of the logic of the operation signal y. Specifically, the delay signal generating circuit 102a changes the logic of the delay signal z from “Low” level to “High” level after the lapse of the preset delay time from the time when the first signal w changes in response to the change of the second signal x.

Then, the first NAND circuit 102b1 keeps the second assist control signal AssistB at “High” level even in response to the change of the logic of the delay signal z because the first signal w is at “Low” level.

Moreover, the second NAND circuit 102b2 keeps the first assist control signal AssistA at “High” level even in response to the change of the logic of the delay signal z because the second signal x is at “Low” level.

As described above, in the case where the second voltage VB falls, the assist control signal generating circuit 102b outputs the first assist control signal AssistA so as to turn off the first assisting switch element PA until the logic of the delay signal z changes after the change of the second signal x.

In other words; even in the case where the load capacitance connected to the first terminal TA is larger than the load capacitance connected to the second terminal TB, the pulse generating circuit 102 does not generate a one-shot pulse signal for turning on the first assisting switch element PA when the second voltage VB falls.

Hence, a “Low” level output signal is outputted from the first terminal TA.

Therefore, in the case of signal transmission from the second terminal TB to the first terminal TA, the bus switch circuit 100 according to the first embodiment can transmit a predetermined signal even when the load capacitance connected to the first terminal TA increases.

As described above, the bus switch circuit according to the first embodiment can transmit a signal with higher reliability.

### Second Embodiment

In the first embodiment, the second power supply voltage VccB is higher than the first power supply voltage VccA (that is, two power supplies).

In a second embodiment, a second power supply voltage VccB is equal to a first power supply voltage VccA (that is, a single power supply). In this case, the level shifter of a pulse generating circuit 102 may be omitted.

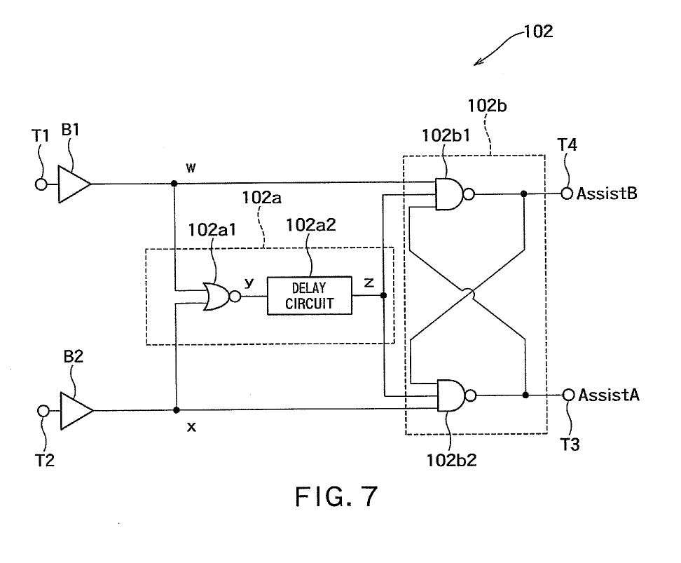

FIG. 7 is a circuit diagram illustrating an example of the circuit configuration of the pulse generating circuit 102 according to the second embodiment. In FIG. 7, the same reference numerals as those of FIG. 4 indicate the same configurations as those of the first embodiment unless otherwise specified. The pulse generating circuit 102 in FIG. 7 is applied to the bus switch circuit 100 of FIG. 4 as in the first embodiment.

As illustrated in FIG. 7, the pulse generating circuit 102 includes a first buffer B1, a second buffer B2, a delay signal generating circuit 102a, and an assist control signal generating circuit 102b.

The first buffer B1 is fed with the voltage of a first terminal TA and outputs a first signal w.

The second buffer B2 is fed with the voltage of a second terminal TB and outputs a second signal x.

As described above, the second power supply voltage VccB is equal to the first power supply voltage VccA. Thus, unlike in the first embodiment, first and second level shifters LS1 and LS2 are omitted in the pulse generating circuit 102 of the second embodiment.

Other configurations of the pulse generating circuit 102 according to the second embodiment are identical to those of the first embodiment.

Moreover, the bus switch circuit 100 including the pulse generating circuit 102 configured thus operates as in the first embodiment.

In other word, also in the case of signal transmission from the second terminal TB to the first terminal TA, the bus switch circuit 100 can transmit a predetermined signal as in the first embodiment even when a load capacitance connected to the first terminal TA increases.

As described above, the bus switch circuit according to the second embodiment can transmit a signal with higher reliability as in the first embodiment.

### Third Embodiment

In the first and second embodiments, a NOR operation is performed on the first and second signals w and x by the NOR circuit, and then the obtained operation signal is delayed by the delay circuit and is outputted as the delay signal.

In a third embodiment, first and second signals w and x are delayed by a delay circuit, a NOR operation is performed on an obtained signal by a NOR circuit, and then the signal is outputted as a delay signal.

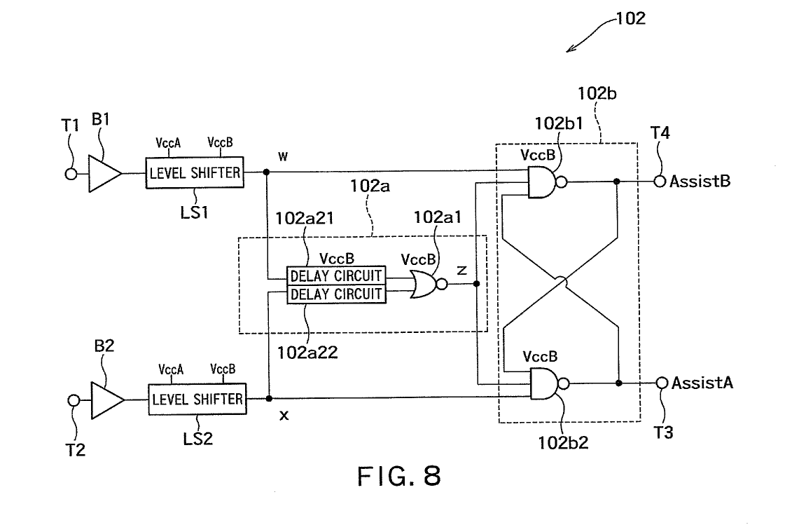

FIG. 8 is a circuit diagram illustrating an example of the circuit configuration of a pulse generating circuit 102 according to the third embodiment. In FIG. 8, the same reference numerals as those of FIG. 4 indicate the same configurations as those of the first embodiment unless otherwise specified. The pulse generating circuit 102 of FIG. 8 is applied to the bus switch circuit 100 of FIG. 4 as in the first embodiment.

As illustrated in FIG. 8, the pulse generating circuit 102 includes, as in the first embodiment, a first buffer B1, a second buffer B2, a first level shifter LS1, a second level shifter LS2, a delay signal generating circuit 102a, and an assist control signal generating circuit 102b.

The delay signal generating circuit 102a outputs, as in the first embodiment, a delay signal z based on the first signal w varying with a first voltage VA applied to a first terminal TA and the second signal x varying with a second voltage VB applied to a second terminal TB.

The delay signal generating circuit 102a includes, for example, a NOR circuit 102a1 and delay circuits 102a21 and 102a22.

The delay circuit 102a21 is fed with the first signal w, delays the inputted first signal w by a preset delay time, and then outputs the signal.

The delay circuit 102a22 is fed with the second signal x, delays the second signal x by the preset delay time, and then outputs the signal.

In the present embodiment, the delay time of the delay circuit 102a21 and the delay time of the delay circuit 102a22 are equal to each other. The delay circuits may have different delay times when necessary.

The NOR circuit 102a1 is fed with the delayed first signal w and the delayed second signal x and outputs the delay signal z obtained by performing a NOR operation on the delayed signals.

Other configurations of the pulse generating circuit 102 according to the third embodiment are identical to those of the first embodiment.

Moreover, the bus switch circuit 100 including the pulse generating circuit 102 configured thus operates as in the first embodiment.

Specifically, in the case where the first voltage VA rises, the pulse generating circuit 102 generates a one-shot pulse signal for turning on a second assisting switch element PB.

Thus, the voltage VB of the second terminal TB is raised to a second power supply voltage VccB (first power supply voltage VccB) and an output signal at a predetermined level is outputted from the second terminal TB. In other words, faster signal transmission is achieved.

In the case where the second voltage VB rises, the pulse generating circuit 102 generates a one-shot pulse signal for turning on a first assisting switch element PA.

Thus, the voltage VA of the first terminal TA is raised to a first power supply voltage VccA and an output signal at the predetermined level is outputted from the first terminal TA. In other words, faster signal transmission is achieved.

Specifically, in the case of signal transmission from the first terminal TA to the second terminal TB, when the first voltage VA rises, the pulse generating circuit 102 generates the one-shot pulse signal for turning on the second assisting switch element PB.

Thus, the voltage VB of the second terminal TB is raised to the second power supply voltage VccB and a “High” level output signal is outputted from the second terminal TB. In other words, faster signal transmission is achieved.

In the case of signal transmission from the second terminal TB to the first terminal TA, when the second voltage VB rises, the pulse generating circuit 102 generates the one-shot pulse signal for turning on the first assisting switch element PA.

Thus, the voltage VA of the first terminal TA is raised to the first power supply voltage VccA and a “High” level output signal is outputted from the first terminal TA. In other words, faster signal transmission is achieved.

As in the first embodiment, even in the case where a load capacitance connected to the first terminal TA is larger than a load capacitance connected to the second terminal TB, when the second voltage VB falls, the pulse generating circuit 102 according to the third embodiment does not generate the one-shot pulse signal for turning on the first assisting switch element PA.

Thus, also in the case of signal transmission from the second terminal TB to the first terminal TA, the bus switch circuit 100 can transmit a predetermined signal as in the first embodiment even when the load capacitance connected to the first terminal TA increases.

As described above, the bus switch circuit according to the third embodiment can transmit a signal with higher reliability as in the first and second embodiments.

### Fourth Embodiment

In the first to third embodiments, the pulse generating circuit outputs the one-shot pulse signal at “Low” level when the input signal rises. In this case, the assisting switch element is turned on by the pulse signal and the output signal is pulled up from the ground voltage to the positive power supply voltage.

In a fourth embodiment, a pulse generating circuit 102 outputs a one-shot pulse signal at “High” level when an input signal falls. The pulse generating circuit 102 is applied to the bus switch circuit of the first embodiment, in which a signal level converting circuit 101 has reversed circuit polarity. In this case, an assisting switch element is turned on by the pulse signal and an output signal is pulled down from a ground voltage to a negative power supply voltage.

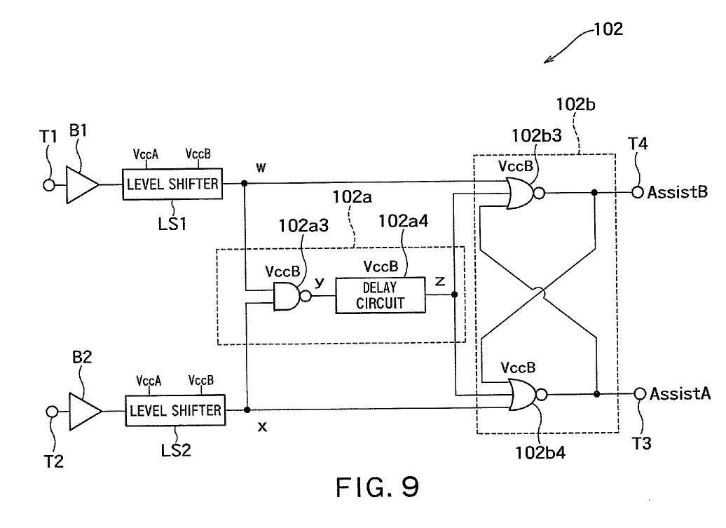

FIG. 9 is a circuit diagram illustrating an example of the circuit configuration of the pulse generating circuit 102 according to the fourth embodiment. In FIG. 9, the same reference numerals as those of FIG. 4 indicate the same configurations as those of the first embodiment unless otherwise specified. As has been discussed, the pulse generating circuit 102 of FIG. 9 is applied to the bus switch circuit in which the signal level converting circuit 101 of FIG. 4 has reversed circuit polarity.

As shown in FIG. 9, as in the first embodiment, the pulse generating circuit 102 includes a first buffer B1, a second buffer B2, a first level shifter LS1, a second level shifter LS2, a delay signal generating circuit 102a, and an assist control signal generating circuit 102b.

As in the first embodiment, the delay signal generating circuit 102a outputs a delay signal z based on a first signal w varying with a first voltage VA applied to a first terminal TA and a second signal x varying with a second voltage VB applied to a second terminal TB.

The delay signal generating circuit 102a includes, for example, a NAND circuit 102a3 and a delay circuit 102a4.

The NAND circuit 102a3 is fed with the first signal w and the second signal x and outputs an operation signal y obtained by performing a NAND operation on the signals w and x.

The delay circuit 102a4 is fed with the operation signal y and outputs the delay signal z obtained by delaying the inputted operation signal y by a preset delay time.

As in the first embodiment, the assist control signal generating circuit 102b outputs a first assist control signal AssistA and a second assist control signal AssistB based on the first signal w, the second signal x, and the delay signal z.

The assist control signal generating circuit 102b includes, for example, a first NOR circuit 102b3 and a second NOR circuit 102b4.

The first NOR circuit 102b3 is fed with the first signal w, the delay signal z, and the first assist control signal AssistA, performs a NOR operation on these signals, and outputs an obtained signal as the second assist control signal AssistB through a terminal T4.

The second NOR circuit 102b4 is fed with the second signal x, the delay signal z, and the second assist control signal AssistB, performs a NOR operation on these signals, and outputs an obtained signal as the first assist control signal AssistA through a terminal T3.

Other configurations of the pulse generating circuit 102 according to the fourth embodiment are identical to those of the first embodiment.

As in the first embodiment, first and second buffers B1 and B2 may be optionally omitted.

In the case where a first power supply voltage VccA is equal to a second power supply voltage VccB, first and second level shifters LS1 and LS2 may be omitted.

The operations of a bus switch circuit 100 including the pulse generating circuit 102 configured thus will be described below.

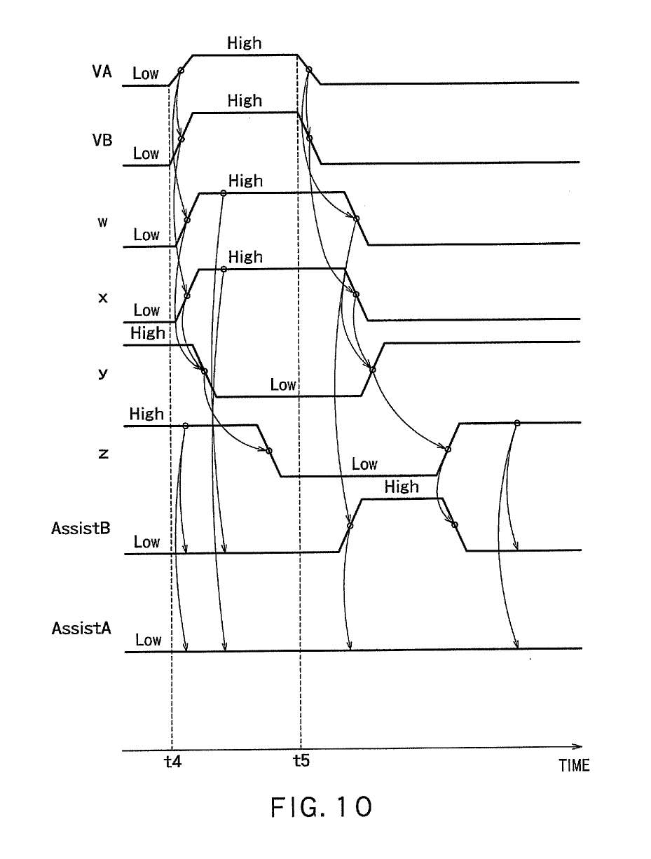

FIG. 10 is a waveform chart showing an example of the signal waveforms of the bus switch circuit 100 including the pulse generating circuit 102 illustrated in FIG. 9. FIG. 10 shows signal transmission from the first terminal TA to the second terminal TB.

As shown in FIG. 10, at time t4, a signal is inputted to the first terminal TA, so that the first voltage VA of the first terminal TA changes from “Low” level (e.g., the negative first power supply voltage VccA) to “High” level (ground voltage). In response to the change of the first voltage VA, the second voltage VB of the second terminal TB starts changing from “Low” level (the negative second power supply voltage VccB) to “High” level (ground voltage).

Then, the first signal w changes from “Low” level to “High” level in response to the change of the first voltage VA.

The first NOR circuit 102b3 of the assist control signal generating circuit 102b keeps the second assist control signal AssistB at “Low” level regardless of the change of the first signal w because the delay signal z is at “High” level.

In response to the change of the second voltage VB, the second signal x changes from “Low” level to “High” level.

The second NOR circuit 102b4 of the assist control signal generating circuit 102b keeps the first assist control signal AssistA at “Low” level regardless of the change of the second signal x because the delay signal z is at “High” level.

The NAND circuit 102a3 of the delay signal generating circuit 102a changes the logic of the operation signal y from “High” level to “Low” level when the second signal x changes to “High” level in response to the change of the first signal w to “High” level.

Then, the delay circuit 102a4 of the delay signal generating circuit 102a changes the logic of the delay signal z from “High” level to “Low” level after the lapse of the delay time from the change of the logic of the operation signal y. Specifically, the delay signal generating circuit 102a changes the logic of the delay signal z from “High” level to “Low” level after the lapse of the preset delay time from the time when the second signal x changes in response to the change of the first signal w.

The first NOR circuit 102b3 keeps the second assist control signal AssistB at “Low” level regardless of the change of the logic of the delay signal z because the first signal w is at “High” level. The second NOR circuit 102b4 keeps the first assist control signal AssistA at “Low” level regardless of the change of the logic of the delay signal z because the second signal x is at “High” level.

As described above, in the case where the first voltage VA rises (changes to the ground voltage), the assist control signal generating circuit 102b outputs the second assist control signal AssistB so as to turn off a second assisting switch element (in this case, an nMOS transistor) PB until the logic of the delay signal z changes after the change of the first signal w.

Thus, in the case where the first voltage VA rises, the pulse generating circuit 102 does not generate a one-shot pulse signal for turning on the second assisting switch element PB. This allows a “High” level output signal to be outputted from the first terminal TA.

Then, at time t5, the first voltage VA of the first terminal TA changes from “High” level to “Low” level. In response to the change of the first voltage VA, the second voltage VB of the second terminal TB starts changing from “High” level to “Low” level.

After that, the first signal w changes from “High” level to “Low” level in response to the change of the first voltage VA. The first NOR circuit 102b3 changes the second assist control signal AssistB from “Low” level to “High” level in response to the change of the first signal w because the logic of the delay signal z is at “Low” level.

In response to the change of the second voltage VB, the second signal x changes from “High” level to “Low” level. The second NOR circuit 102b4 keeps the first assist control signal AssistA at “Low” level regardless of the change of the second signal x because the second assist control signal AssistB is at “High” level.

The NAND circuit 102a3 changes the logic of the operation signal y from “Low” level to “High” level when the second signal x changes to “Low” level in response to the change of the first signal w to “Low” level.

Then, the delay circuit 102a2 changes the logic of the delay signal z from “Low” level to “High” level after the lapse of the delay time from the change of the logic of the operation signal y. Specifically, the delay signal generating circuit 102a changes the logic of the delay signal z from “Low” level to “High” level after the lapse of the preset delay time from the time when the second signal x changes in response to the change of the first signal w.

In response to the change of the logic of the delay signal z, the first NOR circuit 102b3 changes the second assist control signal AssistB from “High” level to “Low” level. The second NOR circuit 102b4 keeps the first assist control signal AssistA at “High” level in response to the change of the logic of the delay signal z.

As described above, in the case where the first voltage VA falls (changes to the first power supply voltage VccA), the assist control signal generating circuit 102b outputs the second assist control signal AssistB so as to turn on the second assisting switch element PB until the logic of the delay signal z changes after the change of the first signal w.

Specifically, in the case where the first voltage VA falls, the pulse generating circuit 102 generates a one-shot pulse signal for turning on the second assisting switch element PB.

Thus, the voltage VB of the second terminal TB is pulled down and a “Low” level output signal is outputted from the second terminal TB. In other words, faster signal transmission is achieved.

Signal transmission from the second terminal TB to the first terminal TA can be similarly described. In this case, the order of operations is changed when the input directions of signals are switched.

In the case of signal transmission from the second terminal TB to the first terminal TA, the bus switch circuit 100 including the pulse generating circuit 102 according to the fourth embodiment can transmit a predetermined signal even when a load capacitance connected to the first terminal TA increases.

As described above, the bus switch circuit according to the fourth embodiment can transmit a signal with higher reliability.

### Fifth Embodiment

In the fourth embodiment, a NAND operation is performed on the first and second signals w and x by the NAND circuit and the obtained operation signal is delayed by the delayed circuit and is outputted as the delay signal.

In a fifth embodiment, first and second signals w and x are delayed by a delay circuit, a NAND operation is performed on an obtained signal by a NAND circuit, and then the obtained signal is outputted as a delay signal.

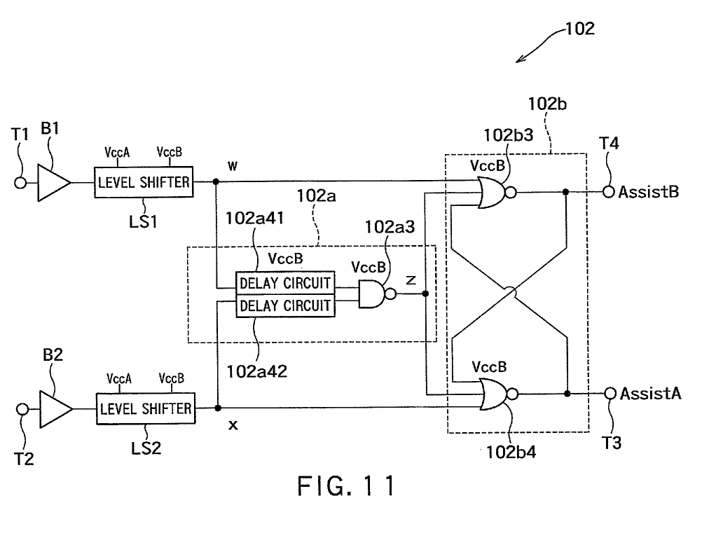

FIG. 11 is a circuit diagram illustrating an example of the circuit configuration of a pulse generating circuit 102 according to the fifth embodiment. In FIG. 11, the same reference numerals as those of FIG. 9 indicate the same configurations as those of the fourth embodiment unless otherwise specified. The pulse generating circuit 102 of FIG. 11 is applied to the bus switch circuit 100 of FIG. 4 as in the first embodiment.

As shown in FIG. 11, as in the fourth embodiment, the pulse generating circuit 102 includes a first buffer B1, a second buffer B2, a first level shifter LS1, a second level shifter LS2, a delay signal generating circuit 102a, and an assist control signal generating circuit 102b.

As in the fourth embodiment, the delay signal generating circuit 102a outputs a delay signal z based on the first signal w varying with a first voltage VA applied to a first terminal TA and the second signal x varying with a second voltage VB applied to a second terminal TB.

As in the fourth embodiment, the delay signal generating circuit 102a includes, for example, a NAND circuit 102a3 and delay circuits 102a41 and 102a42.

The delay circuit 102a41 is fed with the first signal w, delays the inputted first signal w by a preset delay time, and then outputs the signal.

The delay circuit 102a42 is fed with the second signal x, delays the second signal x by the preset delay time, and then outputs the signal.

In the present embodiment, the delay time of the delay circuit 102a41 and the delay time of the delay circuit 102a42 are equal to each other. The delay circuits may have different delay times when necessary.

The NAND circuit 102a3 is fed with the delayed first signal w and the delayed second signal x and outputs the delay signal z obtained by performing a NAND operation on the delayed signals.

Other configurations of the pulse generating circuit 102 according to the fifth embodiment are identical to those of the fourth embodiment.

The operations of a bus switch circuit 100 including the pulse generating circuit 102 configured thus are similar to those of the fourth embodiment.

In other words, also in the case of signal transmission from the second terminal TB to the first terminal TA, the bus switch circuit 100 can transmit a predetermined signal as in the fourth embodiment even when a load capacitance connected to the first terminal TA increases.

As described above, the bus switch circuit according to the fifth embodiment can transmit a signal with higher reliability as in the fourth embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A bus switch circuit comprising:
a signal transmission circuit connected between a first terminal and a second terminal to transmit a signal between the first terminal and the second terminal;
a first switch element connected between the first terminal and a first voltage line fed with a first power supply voltage, and controlled by a first control signal;
a second switch element connected between the second terminal and a second voltage line fed with a second power supply voltage, and controlled by a second control signal;
a delay signal generating circuit that outputs a delay signal based on a first signal varying with a first voltage applied to the first terminal and a second signal varying with a second voltage applied to the second terminal; and
a control signal generating circuit that outputs the first control signal and the second control signal based on the first signal, the second signal, and the delay signal.

2. The bus switch circuit according to claim 1, wherein the signal transmission circuit is a bus switch element.

3. The bus switch circuit according to claim 1, wherein the delay signal generating circuit changes a logic of the delay signal after a lapse of a preset delay time from a time when the first signal changes in response to a change of the second signal,
in the case where the second voltage changes to the second power supply voltage, the control signal generating circuit outputs the first control signal so as to turn on the first switch element until the logic of the delay signal changes after the change of the second signal, and
in the case where the second voltage changes to a ground voltage, the control signal generating circuit outputs the first control signal so as to turn off the first switch element until the logic of the delay signal changes after the change of the second signal.

4. The bus switch circuit according to claim 1, wherein the delay signal generating circuit changes a logic of the delay signal after a lapse of a preset delay time from a time when the second signal changes in response to a change of the first signal,
in the case where the first voltage changes to the first power supply voltage, the control signal generating circuit outputs the second control signal so as to turn on the second switch element until the logic of the delay signal changes after the change of the first signal, and
in the case where the first voltage changes to a ground voltage, the control signal generating circuit outputs the second control signal so as to turn off the second switch element until the logic of the delay signal changes after the change of the first signal.

5. The bus switch circuit according to claim 2, wherein the delay signal generating circuit changes a logic of the delay signal after a lapse of a preset delay time from a time when the second signal changes in response to a change of the first signal,
in the case where the first voltage changes to the first power supply voltage, the control signal generating circuit outputs the second control signal so as to turn on the second switch element until the logic of the delay signal changes after the change of the first signal, and
in the case where the first voltage changes to a ground voltage, the control signal generating circuit outputs the second control signal so as to turn off the second switch element until the logic of the delay signal changes after the change of the first signal.

6. The bus switch circuit according to claim 3, wherein the delay signal generating circuit changes a logic of the delay signal after a lapse of a preset delay time from a time when the second signal changes in response to a change of the first signal,
in the case where the first voltage changes to the first power supply voltage, the control signal generating circuit outputs the second control signal so as to turn on the second switch element until the logic of the delay signal changes after the change of the first signal, and
in the case where the first voltage changes to a ground voltage, the control signal generating circuit outputs the second control signal so as to turn off the second switch element until the logic of the delay signal changes after the change of the first signal.

7. The bus switch circuit according to claim 1, wherein the delay signal generating circuit comprises a NOR circuit that is fed with the first signal and the second signal and outputs an operation signal, and a delay circuit that is fed with the operation signal and outputs the delay signal obtained by delaying the inputted operation signal by a preset delay time, and
the control signal generating circuit comprises a first NAND circuit that is fed with the first signal, the delay signal, and the first control signal and outputs the second control signal, and a second NAND circuit that is fed with the second signal, the delay signal, and the second control signal and outputs the first control signal.

8. The bus switch circuit according to claim 1, wherein the delay signal generating circuit comprises a delay circuit that is fed with the first signal and the second signal, delays the inputted first and second signals by a preset delay time, and then outputs the signals, and a NOR circuit that is fed with the delayed first and second signals and outputs the delay signal, and
the control signal generating circuit comprises a first NAND circuit that is fed with the first signal, the delay signal, and the first control signal and outputs the second control signal, and a second NAND circuit that is fed with the second signal, the delay signal, and the second control signal and outputs the first control signal.

9. The bus switch circuit according to claim 1, wherein the delay signal generating circuit comprises a NAND circuit that is fed with the first signal and the second signal and outputs an operation signal, and a delay circuit that is fed with the operation signal, delays the inputted operation signal by a preset delay time, and then outputs a delay signal being the delayed operation signal, and
the control signal generating circuit comprises a first NOR circuit that is fed with the first signal, the delay signal, and the first control signal and outputs the second control signal, and a second NOR circuit that is fed with the second signal, the delay signal, and the second control signal and outputs the first control signal.

10. The bus switch circuit according to claim 1, wherein the delay signal generating circuit comprises a delay circuit that is fed with the first signal and the second signal, delays the inputted first and second signals by a preset delay time, and then outputs the signals, and a NAND circuit that is fed with the delayed first and second signals and outputs the delay signal, and
the control signal generating circuit comprises a first NOR circuit that is fed with the first signal, the delay signal, and the first control signal and outputs the second control signal, and a second NOR circuit that is fed with the second signal, the delay signal, and the second control signal and outputs the first control signal.

11. The bus switch circuit according to claim 1, wherein the first terminal is connected to a load capacitance larger or smaller than a load capacitance connected to the second terminal.

12. The bus switch circuit according to claim 1, wherein the first terminal is connected to a load capacitance larger than a load capacitance connected to the second terminal.

13. The bus switch circuit according to claim 1, wherein the second power supply voltage is higher than the first power supply voltage.

14. The bus switch circuit according to claim 13, further comprising:
a first buffer that is fed with a voltage of the first terminal and is operated by the first power supply voltage;
a second buffer that is fed with a voltage of the second terminal and is operated by the first power supply voltage;
a first level shifter that outputs the first signal obtained by converting a level of a signal outputted from the first buffer; and
a second level shifter that outputs the second signal obtained by converting a level of a signal outputted from the second buffer.

15. The bus switch circuit according to claim 1, wherein the second power supply voltage is substantially equal to the first power supply voltage.

16. The bus switch circuit according to claim 15, further comprising:
a first buffer that is fed with a voltage of the first terminal and then outputs the first signal; and
a second buffer that is fed with a voltage of the second terminal and then outputs the second signal.

17. The bus switch circuit according to claim 1, wherein the first resistance element is connected between the first terminal and the first voltage line.

18. The bus switch, circuit according to claim 17 wherein the second resistance element is connected between the second terminal and the second voltage line.

19. The bus switch circuit according to claim 1, wherein the first switch element and the second switch element are MOS transistors.
